(19) United States
(12) Patent Application Publication
(10) Pub. No.: US 2018/0076354 A1
(43) Pub. Date: Mar. 15, 2018

(54) ULTRAVIOLET LIGHT EMITTING DIODES WITH TUNNEL JUNCTION

(71) Applicant: OHIO STATE INNOVATION FOUNDATION, Columbus, OH (US)

(72) Inventors: Siddharth RAJAN, Columbus, OH (US); Sriram KRISHNAMOORTHY, Columbus, OH (US); Yuewei ZHANG, Columbus, OH (US)

(21) Appl. No.: 15/562,092

(22) PCT Filed: Mar. 28, 2016
(86) PCT No.: PCT/US16/24552

§ 371 Date: Sep. 27, 2017

Related U.S. Application Data
(60) Provisional application No. 62/139,013, filed on Mar. 27, 2015.

(51) Int. Cl. H01L 33/06; H01L 33/24; H01L 33/00; H01L 33/32; H01L 33/08; H01L 33/46; H01L 33/22

(52) U.S. Cl. CPC H01L 33/06; H01L 33/24; H01L 33/0025; H01L 33/22; H01L 33/325; H01L 33/08; H01L 33/46; H01L 33/0075

(57) ABSTRACT

An example ultraviolet (UV) light emitting diode (LED) is described herein. The UV LED can include an n-doped contact region, an active region configured to emit UV light that is arranged between an n-doped region and a p-doped region, and a tunnel junction. The tunnel junction is arranged between the n-doped contact region and the p-doped region. In addition, the tunnel junction can include a heavily p-doped region, a degenerately n-doped region, and a semiconductor region arranged between the heavily p-doped region and the degenerately n-doped region. Each of the heavily p-doped region and the degenerately n-doped region has a gradually varied material energy bandgap to reduce respective depletion barriers within the heavily p-doped region and the degenerately n-doped region.

### CROSS-REFERENCE TO RELATED APPLICATIONS

This application claims the benefit of U.S. provisional patent application No. 62/139,013, filed on Mar. 27, 2015, and entitled “Hole injection into UV LED through tunnel junction,” the disclosure of which is expressly incorporated herein by reference in its entirety.

### STATEMENT REGARDING FEDERALLY FUNDED RESEARCH

This invention was made with government support under Grant no. ECCS-1408416 awarded by the National Science Foundation. The government has certain rights in the invention.

### BACKGROUND

AlGaN based ultraviolet (UV) light emitting diodes (LED) have been proven to be promising for numbers of applications in multiple areas such as water purification, medical or biological analysis and sensing, etc. In the past decade, many studies on AlGaN based UV LEDs have been reported expanding in a wide UV region from 360 nm (GaN) to 210 nm (AlN). Even though there have been reports on high external quantum efficiency (EQE) above 10%, the EQE of conventional UV LEDs is still much lower than that of InGaN based visible LEDs regardless of the proved high internal quantum efficiency (IQE) achieved for AlGaN UV LED structures with optimized growth conditions.

EQE is determined by the IQE of the active region, injection efficiency and extraction efficiency. Growth on high quality lattice matched substrates and optimization of the active region has enabled high IQE of 50% or even higher. However, the increasing hole activation energy with increasing AlGaN bandgap lowers the thermal activated hole injection efficiency exponentially, leading to a severe problem for achieving high EQE. Moreover, due to the low hole density and the lack of large work function metals, ohmic contact to p-AlGaN is difficult to achieve. Another p-GaN layer is thus grown on p-AlGaN to obtain good ohmic. However, this leads to large absorption loss of the UV light. This leads to significantly lower efficiency (10-100× lower) than visible wavelength emitters, even though high IQE of AlGaN emitters has been achieved. Flip chip bonding is thus necessary to collect light from the backside of the UV LEDs due to poor current spreading and high light absorption in the p-type layers. For example, the light extraction efficiency of conventional AlGaN UV LEDs has been proven to be low, with a maximum achieved value of about 25% using combined light extraction methods, such as device patterning, encapsulation, and epoxy curing. This is far lower than the light extraction efficiency achieved for GaN/InGaN based visible LEDs (e.g., about 70 to 80%), due to the absence of the light absorption layers in visible LEDs. Additionally, the injection and extraction efficiencies contribute to low EQEs of conventional UV LEDs. Except for this, the extra voltage drop across the p-type contact layers and p-GaN/p-AlGaN heterointerface causes low wall plug efficiency (WPE), which is the ratio between output emission power and the input electric power.

### SUMMARY

An example ultraviolet (UV) light emitting diode (LED) is described herein. The UV LED can include an n-doped contact region, an active region configured to emit UV light that is arranged between an n-doped region and a p-doped region, and a tunnel junction. The tunnel junction is arranged between the n-doped contact region and the p-doped region. In addition, the tunnel junction can include a heavily p-doped region, a degenerately n-doped region, and a semiconductor region arranged between the heavily p-doped region and the degenerately n-doped region. Each of the heavily p-doped region and the degenerately n-doped region has a gradually varied material energy bandgap to reduce respective depletion barriers within the heavily p-doped region and the degenerately n-doped region.

Additionally, the semiconductor region can form respective heterojunctions to the heavily p-doped region and the degenerately n-doped region to establish a polarization field that aligns a valence band of the heavily p-doped region and a conduction band of the degenerately n-doped region.

Alternatively or additionally, an energy bandgap of at least one of the heavily p-doped region or the degenerately n-doped region can be larger than an energy bandgap of one or more quantum wells of the active region.

Alternatively or additionally, the gradually varied material energy bandgap of the heavily p-doped region can be a relatively increasing energy bandgap of semiconductor material moving away from an interface with the semiconductor region. Alternatively or additionally, the gradually varied material energy bandgap of the degenerately n-doped region can be a relatively increasing energy bandgap of semiconductor material moving away from an interface with the semiconductor region. Optionally, the semiconductor material can be at least one of aluminum gallium nitride (AlGaN), gallium nitride (GaN), or indium aluminum gallium nitride (InAlGaN).

Alternatively or additionally, the tunnel junction can include an inter band tunnel barrier in the semiconductor region, an n-depletion barrier in the degenerately n-doped region, and a p-depletion barrier in the heavily p-doped region.

Alternatively or additionally, a thickness of the degenerately n-doped region can be from about 1 nm to about 100 nm. Alternatively or additionally, a thickness of the heavily p-doped region can be from about 1 nm to about 100 nm. Alternatively or additionally, a thickness of the semiconductor region can be from about 0.5 nm to about 10 nm.

Alternatively or additionally, the semiconductor region can have lateral material energy bandgap fluctuations comprising a plurality of low and high bandgap regions. Optionally, the semiconductor region can be at least one of indium gallium nitride (InGaN), GaN, AlGaN, or InAlGaN.

Alternatively or additionally, the UV LED can further include an electron blocking region arranged between the active region and the p-doped region.

Alternatively or additionally, the UV LED can further include a second n-doped contact region. The n-doped region is arranged on the second n-doped contact region.

Alternatively or additionally, the tunnel junction can be reversed biased during operation.

Alternatively or additionally, the n-doped contact region can include a roughened surface configured to enhance UV light extraction. Alternatively or additionally, the second n-doped contact region can include a roughened surface configured to enhance UV light extraction.

Alternatively or additionally, the UV LED can further include a dielectric layer arranged on the n-doped contact region. Optionally, the dielectric layer can have a larger energy bandgap than an emission energy of the active region. Optionally, a thickness of the dielectric layer can be from about 10 nm to about 10 μm. Optionally, a refractive index of the dielectric layer can be less than a refractive index of the n-doped contact region. Optionally, the dielectric layer can have a variable refractive index. Optionally, the dielectric layer can include a roughened surface configured to enhance UV light extraction. Optionally, the dielectric layer can be a distribution Bragg reflector.

Alternatively or additionally, at least one of the dielectric layer or the n-doped contact region can include a lattice of spaces. In some implementations, the lattice of spaces can form a photonic crystal structure in the at least one of the dielectric layer or the n-doped contact region. The photonic crystal structure can be configured to enhance UV light extraction. In other implementations, the lattice of spaces can form an array of UV LED columns.

Alternatively or additionally, the UV LED can further include an inverted lattice polarity layer arranged on the n-doped contact region. The inverted lattice polarity layer can have a thickness between about 5 nm and about 10 μm, for example. Optionally, the inverted lattice polarity layer can include a roughened surface. The inverted lattice polarity layer can be obtained by changing the epitaxial growth schemes using different epitaxial methods such as molecular beam epitaxy, metal organic chemical vapor deposition, or hydride vapor phase epitaxy.

Alternatively or additionally, the UV LED can further include a contact region arranged on at least one of the n-doped contact region or the second n-doped contact region. Optionally, the contact region can have a gradually varied material energy bandgap.

An example cascaded ultraviolet (UV) light emitting diode (LED) is described herein. The cascaded UV LED can include a plurality of UV LEDs. One or more of the UV LEDs can be a UV LED as described herein, e.g., including at least an active region, a p-doped region, an n-doped region, and an electron blocking region. The UV LEDs can be connected by one or more tunnel junctions. The plurality of UV LEDs can be arranged between n-doped contact regions. In some implementations, respective quantum well bandgap energies of the active regions of the UV LEDs are the same. In other implementations, respective quantum well bandgap energies of the active regions of the UV LEDs are different.

An example method of manufacturing an ultraviolet (UV) light emitting diode (LED) is described herein. The method can include forming a lower n-doped contact region on a substrate; forming an n-doped cladding layer on the lower n-doped contact region; forming an active region configured to emit UV light on the n-doped cladding layer; forming an electron blocking layer on the active region; forming an p-doped cladding layer on the electron blocking layer; forming a tunnel junction on the p-doped cladding layer; and forming an upper n-doped contact region on the tunnel junction. In addition, the tunnel junction can include a heavily p-doped region, a degenerately n-doped region, and a semiconductor region arranged between the heavily p-doped region and the degenerately n-doped region. Each of the heavily p-doped region and the degenerately n-doped region has a gradually varied material energy bandgap to reduce respective depletion barriers within the heavily p-doped region and the degenerately n-doped region.

Other systems, methods, features and/or advantages will be or may become apparent to one with skill in the art upon examination of the following drawings and detailed description. It is intended that all such additional systems, methods, features and/or advantages be included within this description and be protected by the accompanying claims.

### BRIEF DESCRIPTION OF THE DRAWINGS

The components in the drawings are not necessarily to scale relative to each other. Like reference numerals designate corresponding parts throughout the several views.

FIG. 1 is a schematic diagram illustrating an example tunnel injected UV LED according to implementations described herein.

FIG. 2A is a schematic diagram illustrating the tunnel junction stack of FIG. 1.

FIG. 2B illustrates the lateral fluctuations of the semiconductor region of FIG. 1.

FIG. 2C illustrates example band diagrams of the tunnel junction stack of FIG. 1.

FIG. 3 illustrates the submicropixel structure of example contact regions according to an implementation described herein.

FIG. 4 illustrates an example cascaded UV LED according to an implementation described herein.

FIG. 5 is a schematic diagram illustrating surface roughening of a dielectric layer of an example tunnel injected UV LED according to an implementation described herein.

FIG. 6 is a schematic diagram illustrating surface roughening of both a dielectric layer and the top n-type contact layer of an example tunnel injected UV LED according to an implementation described herein.

FIG. 7 is a schematic diagram illustrating a nano-sized tunnel junction UV LED array enabled by surface texturing according to an implementation described herein.

FIG. 8 is a schematic diagram illustrating a nano-sized tunnel junction UV LED array with sidewall surface roughening for enhanced light scattering according to an implementation described herein.

FIG. 9 is a schematic diagram illustrating bottom side light extraction of an example tunnel injected UV LED with a reflecting layer (such as dielectric distributed reflector) according to an implementation described herein.

FIG. 10 illustrates another example cascaded UV LED according to an implementation described herein.

FIG. 11 is a flow diagram illustrating example operations for manufacturing an AlGaN-based UV LED according to an implementation described herein.

### DETAILED DESCRIPTION

Unless defined otherwise, all technical and scientific terms used herein have the same meaning as commonly understood by one of ordinary skill in the art. Methods and materials similar or equivalent to those described herein can be used in the practice or testing of the present disclosure. As used in the specification, and in the appended claims, the singular forms “a,” “an,” “the” include plural referents unless the context clearly dictates otherwise. The term “comprising” and variations thereof as used herein is used synonymously with the term “including” and variations thereof and are open, non-limiting terms. The terms “optional” or “optionally” used herein mean that the subsequently described feature, event or circumstance may or may not occur, and that the description includes instances where said feature, event or circumstance occurs and instances where it does not. Ranges may be expressed herein as from “about” one particular value, and/or to “about” another particular value. When such a range is expressed, an aspect includes from the one particular value and/or to the other particular value. Similarly, when values are expressed as approximations, by use of the antecedent “about,” it will be understood that the particular value forms another aspect. It will be further understood that the endpoints of each of the ranges are significant both in relation to the other endpoint, and independently of the other endpoint. While implementations will be described for an AlGaN based tunnel injected UV LED, it will become evident to those skilled in the art that the implementations are not limited thereto, but are applicable for other III-Nitride based tunnel injected UV LEDs.

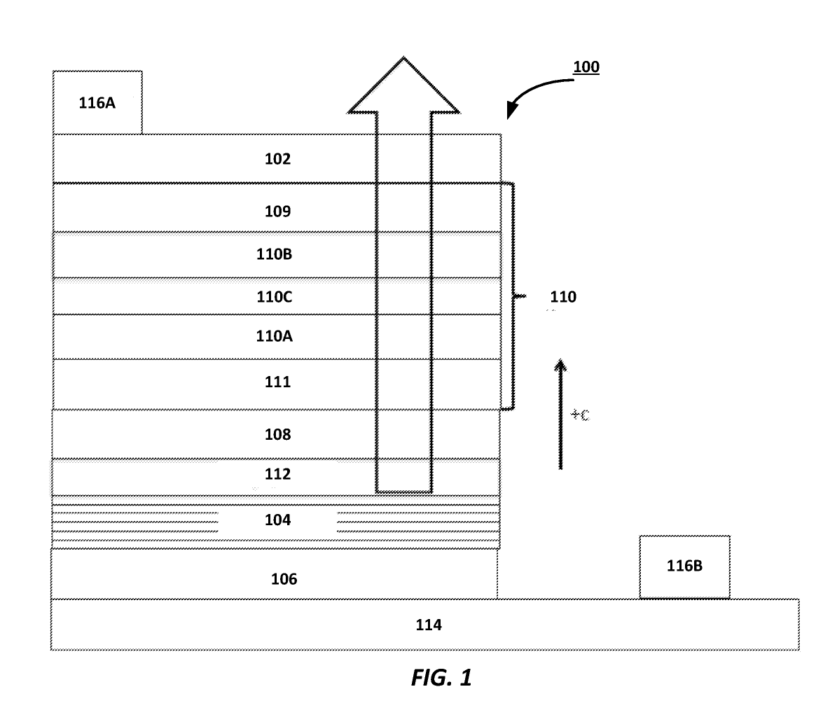

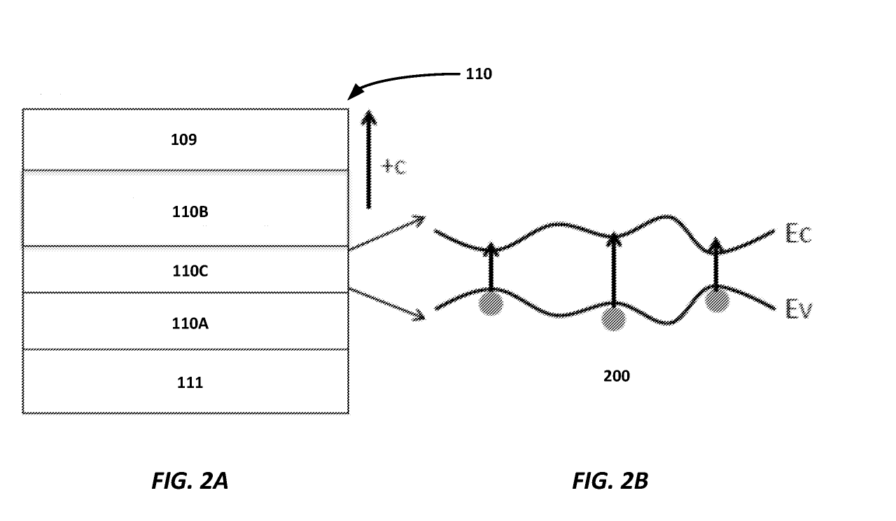

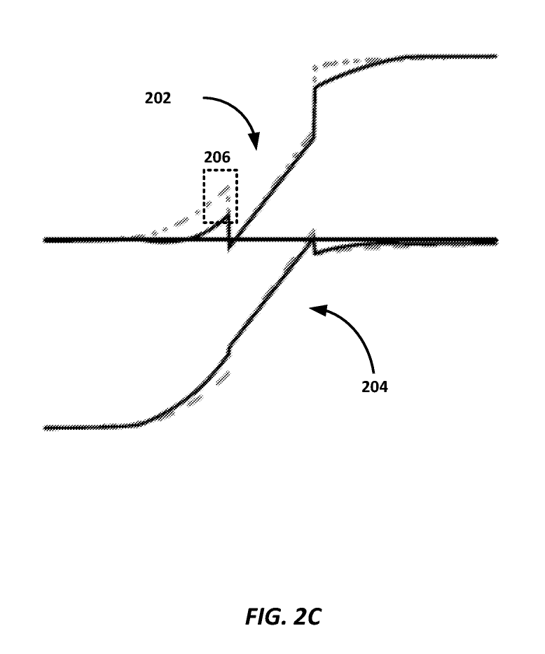

Referring now to FIGS. 1 and 2A-2C, an example tunnel injected UV LED is described. As noted above, in some implementations described herein, the tunnel injected UV LED is an AlGaN based tunnel injected UV LED. It should be understood, however, that the tunnel injected UV LED can be another III-Nitride based tunnel injected UV LED. The UV LED 100 can include an active region 104 arranged between an n-doped region 106 (also referred to as n-type cladding layer) and a p-doped region 108 (also referred to as p-type cladding layer). Each of the n-doped region 106 and the p-doped region 108 can be AlGaN such as Al_{0.3}Ga_{0.7}N, for example. The AlGaN of the n-doped region 106 can be silicon (Si) doped with a concentration (i.e., [Si]) of about 3×10¹⁸ cm⁻³, and the AlGaN of the p-doped region 108 can be magnesium (Mg) doped with a concentration (i.e., [Mg]) of about 2×10¹⁹ cm⁻³. The active region 104 can be configured to emit UV light. The arrow in FIG. 1 illustrates UV light emission. For example, the active region 104 can include one or more quantum wells that emit UV light. The active region 104 can include three AlGaN quantum wells such as Al_{0.2}Ga_{0.8}N quantum wells, for example. Additionally, the UV LED 100 can include an electron blocking region 112 (also referred to as electron blocking layer) arranged between the active region 104 and the p-doped region 108. The electron blocking region 112 can be p-type AlGaN, for example. It should be understood that the materials, compositions, and/or doping concentrations are provided only as examples.

The UV LED 100 can also include a tunnel junction 110. As shown in FIG. 1, the tunnel junction 110 can be arranged between an n-doped contact region 102 (i.e., the top or upper side contact of the UV LED 100) and p-doped region 108. The n-doped contact region 102 can optionally be transparent, which facilitates light extraction from the top/upper side of the UV LED (i.e., flip chip bonding is not required). Additionally, the UV LED 100 can further include a second n-doped contact region 114 (i.e., the bottom or lower side contact of the UV LED 100). The second n-doped contact region 114 can optionally be transparent, which facilitates light extraction from the bottom/lower side of the UV LED. As shown in FIG. 1, the n-doped region 106 can be arranged on the second n-doped contact region 114.

The tunnel junction 110 can include a heavily p-doped region 110A, a degenerately n-doped region 110B, and a semiconductor region 110C arranged between the heavily p-doped region 110A and the degenerately n-doped region 110B. The heavily p-doped region 110A and the degenerately n-doped region 110B can be a semiconductor material such as AlGaN, GaN, or InAlGaN, and the semiconductor region 110C can be a semiconductor material such as InGaN, GaN, AlGaN, or InAlGaN. The heavily p-doped region 110A is doped to such a high level that it begins to behave more like a good conductor (e.g., metal) and less like a semiconductor. The heavily p-doped region 110A can be doped with a doping density from about 5×10¹⁶ cm⁻³ to about 1×10²² cm⁻³. For example, the heavily p-doped region 110A can be Mg-doped AlGaN with [Mg] of about of 5×10¹⁹ cm⁻³. Similarly, the degenerately n-doped region 110B is doped to such a high level that it begins to behave more like a good conductor (e.g., metal) and less like a semiconductor. The degenerately n-doped region 110B can be doped with a doping density from about 5×10¹⁶ cm⁻³ to about 1×10²² cm⁻³. For example, the degenerately n-doped region 110B can be Si-doped AlGaN with [Si] of about of 1×10²⁰ cm⁻³. It should be understood that the materials, compositions, and/or doping concentrations are provided only as examples.

Additionally, each of the heavily p-doped region 110A and the degenerately n-doped region 110B can have a gradually varied material energy bandgap. The bandgap of the heavily p-doped region 110A and the degenerately n-doped region 110B can be varied through engineering of the regions, for example, through selection of materials, material compositions, doping concentrations, etc. For example, the energy bandgap of the semiconductor material of the heavily p-doped region 110A can increase moving away from an interface with the semiconductor region 110C, and the energy bandgap of the semiconductor material of the degenerately n-doped region 110B can increase moving away from an interface with the semiconductor region 110C. For example, the degenerately n-doped region 110B can be graded from about Al_{0.22}Ga_{0.78}N at the interface with the semiconductor region 110C to about Al_{0.3}Ga_{0.7}N in region 109 of FIG. 1. Additionally, the heavily p-doped region 110A can be graded from about Al_{0.22}Ga_{0.78}N at the interface with the semiconductor region 110C to about Al_{0.3}Ga_{0.7}N in region 111 of FIG. 1. Although example AlGaN composition gradings are provided above, this disclosure contemplates that the AlGaN can be graded from AlₓGa₁₋ₓN (e.g., in region 109 or 111) to Al_{y}Ga_{1-y}N (x≧y≧0) at the heterojunctions (e.g., at the interface with the semiconductor region 110C). It should be understood that the materials and compositions are provided only as examples.

The tunnel junction 110 has an inter band tunnel barrier in the semiconductor region 110C, an n-depletion barrier in the degenerately n-doped region 110B, and a p-depletion barrier in the heavily p-doped region 110A. The graded material energy bandgaps of the heavily p-doped region 110A and the degenerately n-doped region 110B reduce a depletion barrier within the heavily p-doped region 110A and the degenerately n-doped region 110B. For example, the graded material energy bandgap reduces the p-depletion barrier in the heavily p-doped region 110A, and the graded material energy bandgap reduces the n-depletion barrier in the degenerately n-doped region 110B.

As described herein, the heavily p-doped region 110A can be a semiconductor material such as AlGaN, GaN, or InAlGaN. Optionally, a thickness of the heavily p-doped region 110A can be from about 1 nm to about 110 nm. Additionally, the degenerately n-doped region 110B can be a semiconductor material such as AlGaN, GaN, or InAlGaN. Optionally, a thickness of the degenerately n-doped region 110B can be from about 1 nm to about 110 nm. Further, the semiconductor region 110C can be a semiconductor material such as InGaN, GaN, AlGaN, or InAlGaN. Optionally, a thickness of the semiconductor region 110C can be from about 0.5 nm to about 10 nm.

Referring now to FIG. 2A, the tunnel junction stack of FIG. 1 is shown. As described above, the tunnel junction 110 includes the heavily p-doped region 110A, the degenerately n-doped region 110B, and the semiconductor region 110C arranged between the heavily p-doped region 110A and the degenerately n-doped region 110B. The semiconductor region 110C can form respective heterojunctions to the heavily p-doped region 110A and the degenerately n-doped region 110B, which establish a polarization field that aligns a valence band of the heavily p-doped region 110A and a conduction band of the degenerately n-doped region 110B. In other words, the high polarization charge density at the heavily p-doped region 110A/semiconductor region 110C interface (e.g., a first heterojunction) and the degenerately n-doped region 110B/semiconductor region 110C interface (e.g., a second heterojunction), respectively, leads to a high polarization field. This polarization field cause band bending across the semiconductor region 110C, which aligns a valence band of the heavily p-doped region 110A and a conduction band of the degenerately n-doped region 110B. This band bending occurs over a short distance (e.g., the thickness of the semiconductor region 110C, which is from about 0.5 nm to about 10 nm).

FIG. 2C illustrates the band diagram of the tunnel junction 110. As described above, the tunneling barrier includes an inter band tunnel barrier in the semiconductor region 110C, an n-depletion barrier in the degenerately n-doped region 110B, and a p-depletion barrier in the heavily p-doped region 110A. The band diagrams for the degenerately n-doped region 110B is labeled 202, and the band diagrams for the heavily p-doped region 110A is labeled 204. Additionally, the solid lines correspond to the band diagrams when the semiconductor materials have a gradually varied material energy bandgap as described herein, while the dashed lines correspond to the band diagrams for the semiconductor materials without gradually varied material energy bandgap. As shown in FIG. 2C, the graded material energy bandgaps reduce the depletion barriers, particularly for n-depletion barrier in the degenerately n-doped region 110B as shown by dotted box 206 in FIG. 2C. Additionally, the semiconductor region 110C can have lateral material energy bandgap fluctuations 200 including a plurality of low and high bandgap regions as shown in FIG. 2B. Interband tunneling can happen at relatively low material energy bandgap sites in the semiconductor region 110C with high tunnel probabilities, while the average material energy bandgap in the semiconductor region 110C is relatively high. Thus, the lateral material energy bandgap fluctuation assists interband tunneling, and at the same time prevents cracking caused by large lattice mismatch between the semiconductor region 110C and the heavily p-doped region 110A/the degenerately n-doped region 110B, respectively.

In order to obtain high tunneling probability and thus low tunneling resistance and low voltage drop across the tunnel junction 110, the semiconductor material energy bandgaps of each of the heavily p-doped region 110A and the degenerately n-doped region 110B can be graded as described herein. The graded material energy bandgaps form relatively lower energy bandgap semiconductor material (e.g., lower Al content AlGaN) at the interfaces between the heavily p-doped region 110A and the degenerately n-doped region 110B, respectively, and the semiconductor region 110C (i.e., the first and second heterojunctions described herein) and relatively higher energy bandgap semiconductor material (e.g., higher Al content AlGaN) moving away from the heterojunctions. When the UV LED 100 is reverse biased, electrons tunnel across this small distance from the valence band in the heavily p-doped region 110A to the conduction band in the degenerately n-doped region 110B, and the holes created in the heavily p-doped region 110A are injected into the active region 104. The only absorbing layer in the UV LED 100 is the semiconductor region 110, which causes minimal absorption loss of the emitted light. As a result, the UV light can be extracted from the top/upper side of the UV LED (i.e., through the n-doped contact region 102). Accordingly, the light extraction efficiency of the UV LED 100 can be as high as GaN-based visible LEDs using varying light extraction techniques.

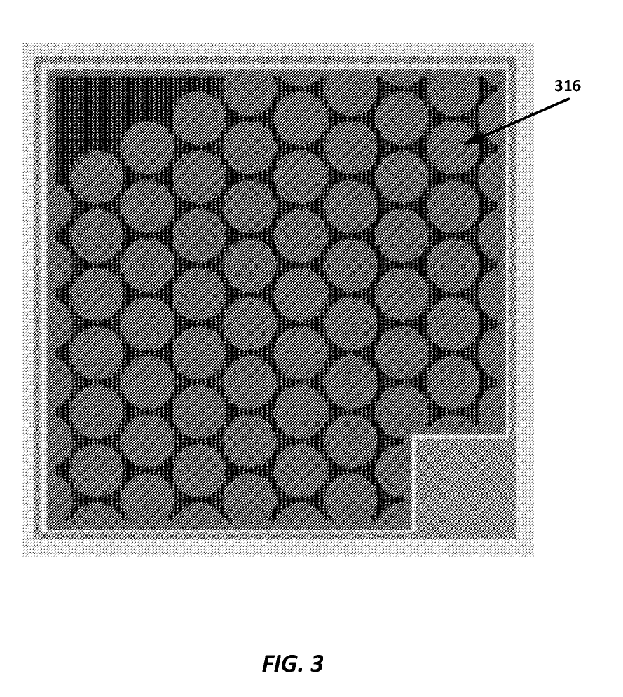

The UV LED 100 can further include contact region 116A or 116B arranged on the n-doped contact region 102 or the second n-doped contact region 114, respectively. For example, as shown in FIG. 1, a contact region 116A is arranged on the n-doped contact region 102, and a contact region 116B is arranged on the second n-doped contact region 114. The contact regions are collectively referred to herein as “contact region 116.” The contact region 116 provides the means for making ohmic contact with the n-doped contact region 102 and/or the second n-doped contact region 114. In some implementations, the n-doped contact region 102 and/or the second n-doped contact region 114 form contacts to high conductance semiconductor material, which connect the n-doped contact region 102 and/or the second n-doped contact region 114 to metal contacts. The contact region 116 can be a semiconductor and/or conductive (e.g., metal) contact deposited directly onto the n-doped contact region 102 and/or the second n-doped contact region 114, for example. In some implementations, the contact region 116 can be conductive material. In some implementations, the contact region 116 can be semiconductor material such as AlGaN (or other III-Nitride material). Optionally, the contact region 116 can have a gradually varied material energy bandgap. For example, the relative material energy bandgap of the semiconductor material (e.g., AlGaN) of the contact region 116 can decrease moving away from its interface with the n-doped contact region 102 and/or the second n-doped contact region 114. In other words, the semiconductor material of the contact region 116 can have a relatively large bandgap at the interface with the contact region graded to a relatively small bandgap at the interface with air. The graded material energy bandgap of the contact region 116 helps set up a transition region between metal contacts and the relatively high material energy bandgap n-doped contact region 102 and/or second n-doped contact region 114. Additionally, as described herein, the emitted UV light can be collected directly from the top or upper side of the UV LED 100 due to the lack of p-doped (e.g., p-GaN) contact layer. In other words, flip chip bonding is not required. To enhance light extraction, the contact regions 316 can be designed with a micropixel structure as shown in FIG. 3. The diameter of the contact regions 316 can be designed to have optical aperture characteristic for the UV emitted light to minimize the blocked light by the contacts.

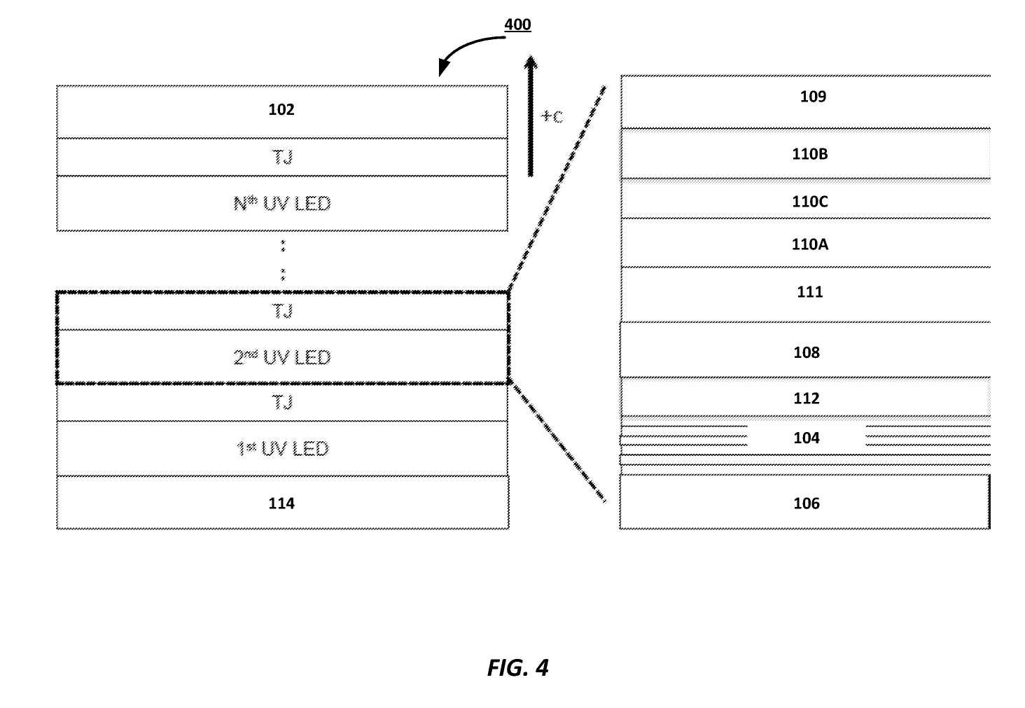

Referring now to FIG. 4, an example cascaded UV LED 400 is described. In a cascaded UV LED, multiple UV LED active regions are connected via tunnel junctions. For example, the cascaded UV LED can include a plurality of UV LEDs (e.g., 1^{st} UV LED, 2^{nd} UV LED, . . . , Nth UV LED). One or more of the UV LEDs can be a UV LED as described herein, e.g., including at least an active region 104, an n-doped region 106, a p-doped region 108, and an electron blocking region 112. The UV LEDs are connected by a tunnel junction TJ(s). The tunnel junction TJ can be the tunnel junction 110 as described with respect to FIG. 1. The plurality of UV LEDs can be arranged between n-doped contact regions. In some implementations, respective quantum well material energy bandgaps of the active regions of the UV LEDs are the same. In this case, the active regions of the plurality of UV LEDs can be designed to have a single wavelength emission, so that the emission power will be increased at a same injection current as compared to a single UV LED structure. The cascaded UV LED can therefore be operated with high output power at a low current injection regime, which is close to the EQE maxima of the device. As a result, the efficiency droop problem can be avoided. In other implementations, respective quantum well material energy bandgap of the active regions of the UV LEDs are different. In this case, the active regions of the plurality of UV LEDs can be designed to have different wavelength emissions (e.g., multiple UV peaks with different wavelengths). Respective electrical contacts can be provided on each n-doped contact region such that single UV peaks with different wavelengths can be obtained by operating different UV LEDs.

Various light extraction techniques have been developed for conventional UV LEDs. However, conventional UV LEDs typically include p-doped contact region (e.g., p-doped GaN) arranged on the top or upper side of the device. Due to absorption by, and high resistance of, the p-doped contact region, light extraction techniques are applied only to the bottom or lower side of conventional UV LEDs. In other words, flip chip bonding is required in conventional UV LEDs. On the other hand, as described above, the UV LED 100 described herein includes the n-doped contact region 102 arranged on the top or upper side of the device. In particular, the UV LED 100 includes the tunnel junction 110 and the n-doped contact region 102 instead of a p-doped contact region on the top or upper side of the device. The top or uppermost layer of the UV LED 100 is an n-type III-Nitride, which can optionally be grown thicker for better current spreading. Additionally, light extraction from the UV LED 100 described herein can optionally be achieved and optionally enhanced as described below. For example, light extraction can be achieved by surface roughening of a contact layer, surface roughening of a dielectric material, providing a dielectric distribution Bragg reflector (DBR) coating, and/or deposition of a photonic crystal to bend the transverse-magnetic (TM) light.

In some implementations, the n-doped contact region 102 can optionally include a roughened surface configured to enhance UV light extraction. Alternatively or additionally, the second n-doped contact region 114 can include a roughened surface configured to enhance UV light extraction. In other words, the surface of either the n-doped contact region 102 and/or the second n-doped contact region 114, both of which are exposed to the environment, can be roughened such that the surface is not planar. Surface roughening can be achieved using any technique known in the art including, but not limited to, wet etching or dry etching techniques. Random surface roughening can be used to minimize internal light reflection at the semiconductor (e.g., either the n-doped contact region 102 and/or the second n-doped contact region 114)/air interface. With a roughened surface, there is no clear limitation on the critical angle for light extraction, and the back reflection can be avoided almost completely. Additionally, the n-doped contact region 102 can optionally have an inverted lattice polarity in the upper most (e.g., closest to air interface) portion (e.g., from about 5 nm to about 10 μm depth). Roughening techniques such as photoelectrochemical etching can be used to achieve the inverted lattice polarity. For example, inverted lattice polarity in the n-doped contact region 102 can be obtained by changing the epitaxial growth schemes using epitaxial methods such as molecular beam epitaxy, metal organic chemical vapor deposition, or hydride vapor phase epitaxy.

An example surface roughening technique uses self-assembled metal nano-clusters (also referred to as nano-sized clusters) as nano-size mask for inductively coupled plasma reactive ion etching (ICP-RIE) dry etching of the top or upper surface of the n-doped contact region 102 of UV LED 100 described with respect to FIG. 1. The processing includes deposition of a dielectric layer on the top or upper surface of the n-doped contact region 102, and followed by deposition of a thin metal layer (also referred to a thin metal film). The metal layer can be any high melting temperature metal or alloy. Rapid thermal annealing is then carried out to reorganize the thin metal film into nano-sized clusters. Dry etching of the n-doped contact region 102 can thus be used to define nano-columns on the surface for enhancing UV light extraction. The metal clusters can be removed using corresponding wet etching solutions. Optionally, the dielectric layer remains on the AlGaN surface to increase light extraction.

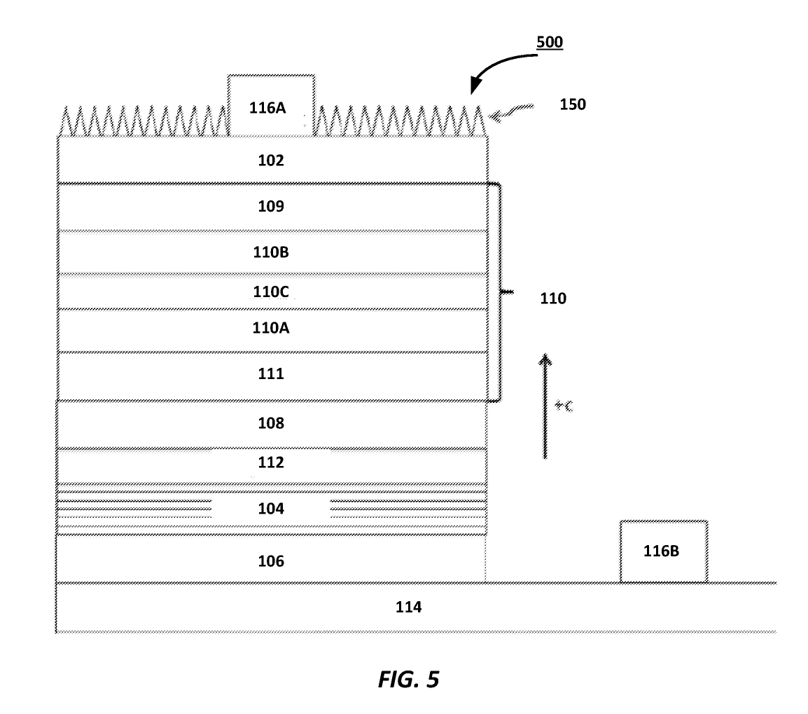

Referring now to FIG. 5, surface roughening of a dielectric layer of an example tunnel injected UV LED 500 is shown. UV LED 500 is similar in many respects to UV LED 100 of FIG. 1, and therefore, a number of the features of UV LED 500 are not described in detail below. As shown in FIG. 5, the UV LED 500 can further include a dielectric layer 150 arranged on the n-doped contact region 102. The dielectric layer 150 can be roughened as described herein such that its surface is not planar. Optionally, the dielectric layer 150 can have a larger bandgap than an emission energy of the active region 104. Optionally, a thickness of the dielectric layer 150 can be from about 10 nm to about 10 μm. Optionally, the thickness of the dielectric layer 150 can be variable or non-uniform across the n-doped contact region 102. Optionally, a refractive index of the dielectric layer 150 can be less than a refractive index of the n-doped contact region 102. Optionally, the dielectric layer 150 can have a varying refractive index. For example, the dielectric layer 150 can have a relatively high refractive index at the interface with the n-doped contact region 102 that is graded to a relatively low refractive index at the interface with the air. Optionally, the dielectric layer can include a roughened surface configured to enhance UV light extraction.

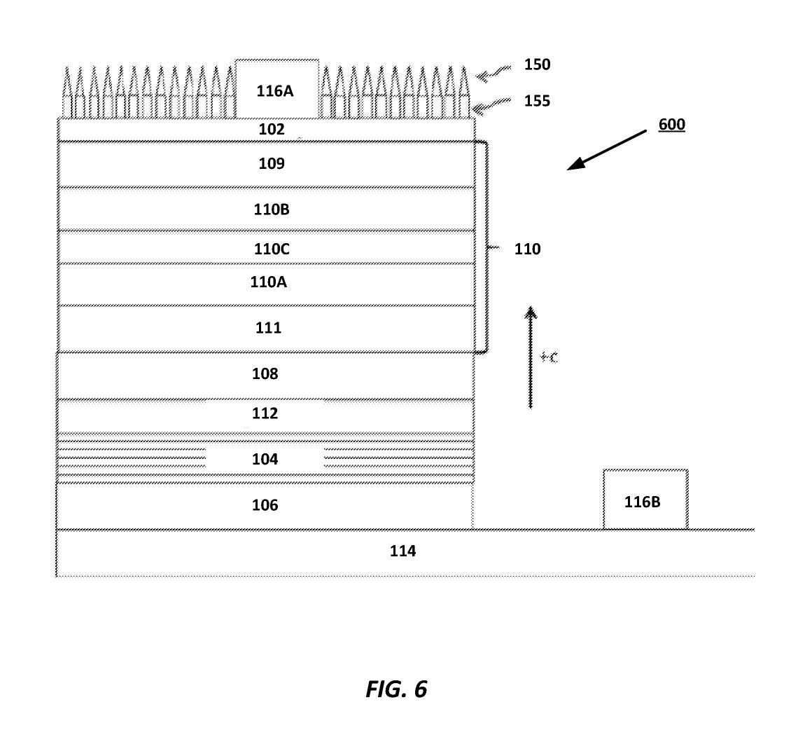

Referring now to FIG. 6, surface roughening of both a dielectric layer and the top n-type contact layer of an example tunnel injected UV LED 600 is shown. UV LED 600 is similar in many respects to UV LED 100 of FIG. 1, and therefore, a number of the features of UV LED 600 are not described in detail below. As shown in FIG. 6, the UV LED 600 can further include a dielectric layer 150 arranged on the n-doped contact region 102. In addition, one or more nano-columns 155 can be formed in the dielectric layer 150 and/or the n-doped contact region 102. In some implementations, the nano-columns 155 are formed only in the dielectric layer 150, while in other implementations the nano-columns 155 are formed both in the dielectric layer 150 and the n-doped contact region 102. Each of the nano-columns 155 can optionally have a uniform diameter, for example, from about 10 nm to about 5 μm. In addition, spacing between each of the nano-columns can optionally be uniform, for example, from about 10 nm to about 10 μm. It should be understood that the shape, size, and/or spacing of the nano-columns are provided only as examples and that the nano-columns can have other shapes, sizes, and/or spacing.

The arrangement of the nano-columns 155 can be controlled during the process for surface roughening. For example, when the example surface roughening technique described above is employed, the size of the nano-columns 155 can vary with both the thickness of the thin metal film and the annealing temperature. The self-assembled metal nano-clusters can be controlled to have near periodic distribution. This can be used to define a photonic crystal structure in the dielectric layer 150 and/or the n-doped contact region 102. For example, the nano-columns can be formed to define a lattice of spaces between the nano-columns, which defines the photonic crystal structure. Additionally, the height of the nano-columns 155 can be controlled by the etching depth. The lattice of spaces can be filled with air or dielectrics to form periodic change in the refractive index. The photonic crystal structure can therefore be designed to enhance UV light extraction by changing the lattice constant and depth of the spaces to match different wavelength emissions. For example, the size of the spaces can be changed to accommodate different emission wavelength from the active regions. The size/spacing of the nano-columns 155 and the dielectric refractive index of the filling material can be designed to match the transverse magnetic (TM) modes, so that TM light could be extracted from the top surface instead of from the side wall of the UV LED. This is particularly useful for the extraction of UV or deep UV lights, which have a TM dominant light emission.

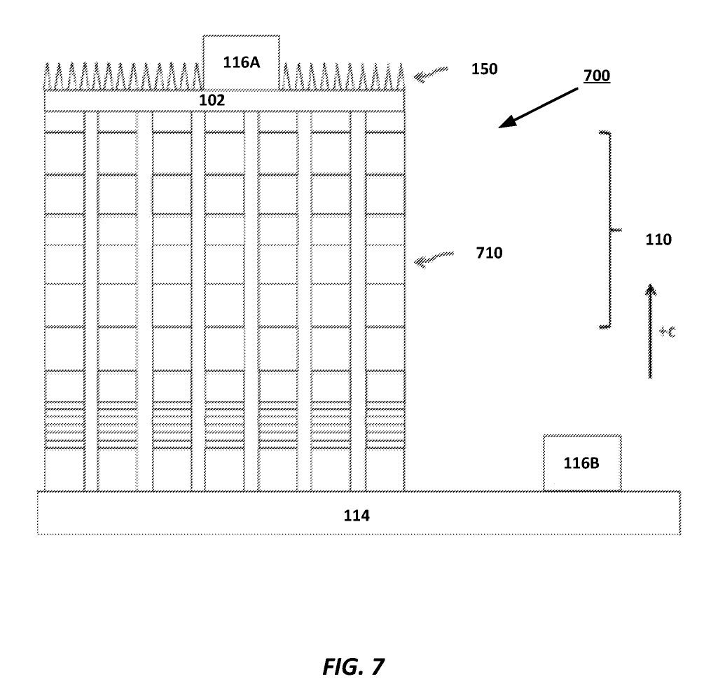

Referring now to FIG. 7, a nano-sized tunnel junction UV LED array enabled by surface texturing is shown. UV LED 700 is similar in many respects to UV LED 100 of FIG. 1, and therefore, a number of the features of UV LED 700 are not described in detail below. As shown in FIG. 7, the UV LED 700 can further include a dielectric layer 150 arranged on the n-doped contact region 102. In addition, one or more nano-columns 710 can be formed in the UV LED 700 as described above. As compared to the nano-columns of FIG. 6, the nano-columns 710 are etched to reach the second n-doped contact region 114 to form a nano UV LED array (e.g., a plurality of nano UV LEDs). The etching can be accomplished by dry etching or wet etching, for example, by wet etching using acids. Optionally, the diameter of each of each UV LED in the array can be from about 10 nm to about 20 μm, for example. It should be understood that the shape, size, and/or spacing of the nano UV LED array is provided only as example and that the nano UV LED array 710 can have other shapes, sizes, and/or spacing.

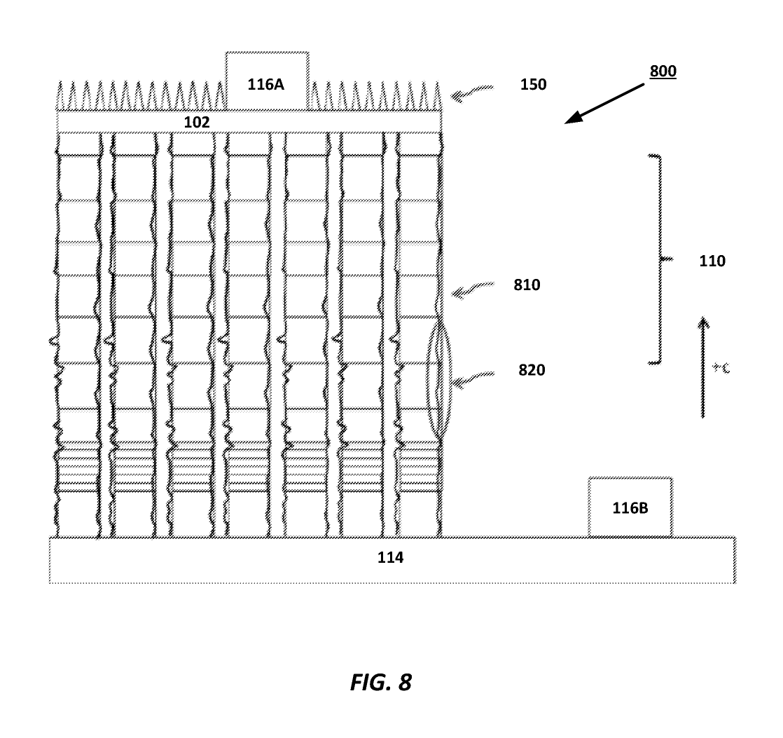

Referring now to FIG. 8, a nano-sized tunnel junction UV LED array with sidewall surface roughening for enhanced light scattering from the side of the device is shown. UV LED 800 is similar in many respects to UV LED 100 of FIG. 1, and therefore, a number of the features of UV LED 800 are not described in detail below. As shown in FIG. 8, the UV LED 800 can further include a dielectric layer 150 arranged on the n-doped contact region 102. In addition, one or more nano-columns 810 can be formed in the UV LED 800 as described above. Similarly to FIG. 7, the nano-columns 810 are etched to reach the second n-doped contact region 114 to form a nano UV LED array (e.g., a plurality of nano UV LEDs). Additionally, further etching of the sidewalls 820 of the nano-columns 810 gives subwavelength nano-structures, which improves UV light extraction especially of the TM polarized light. The etching can be accomplished by dry etching or wet etching, for example, by wet etching using acids. The nano-columns 810 increase the sidewall area, while the sidewall roughening reduces internal reflection at the air/semiconductor boundary. As a result, the TM light emitted from the active region can be extracted more effectively.

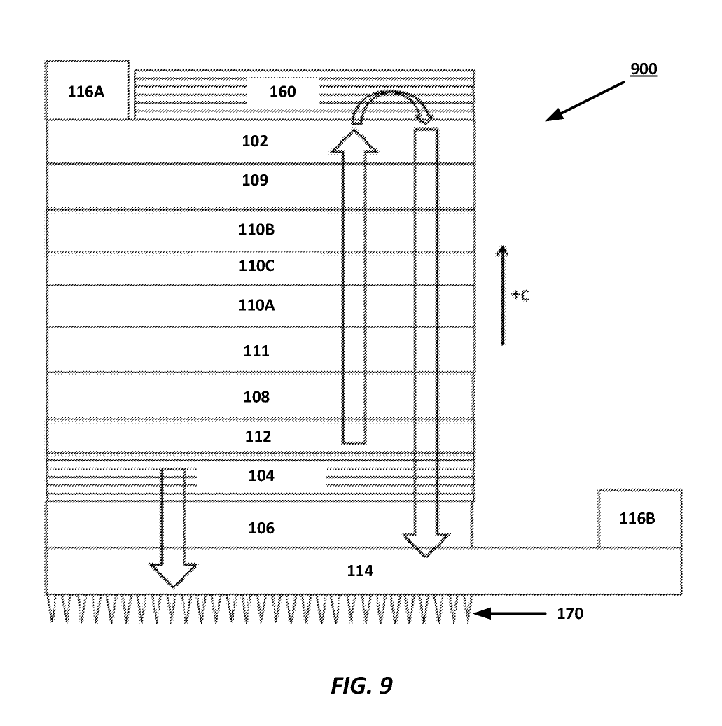

Referring to FIG. 9, bottom side light extraction of an example tunnel injected UV LED 900 with a reflecting layer is shown. UV LED 900 is similar in many respects to UV LED 100 of FIG. 1, and therefore, a number of the features of UV LED 900 are not described in detail below. As shown in FIG. 9, the UV LED 900 can further include a reflecting layer 160 arranged on the n-doped contact region 102. The reflecting layer 160 can be a dielectric distribution Bragg reflector (DBR) instead of a single dielectric layer (e.g., as shown in FIGS. 5-8). The DBR can be formed on either a planar or roughened surface of the n-doped contact region 102 with or without nano-columns as described herein. The refractive index of the DBR can be controlled such that that the back reflection coefficient at the interface between the n-doped contact region 102 and the DBR of the emitted UV wavelength is 1. The arrows in FIG. 9 illustrate the back reflection of UV light within the UV LED 900. The emitted UV light can therefore be collected from the bottom or lower side of the UV LED 900. As compared to the UV LEDs of FIGS. 1 and 4-8, flip chip bonding is required to extract the emitted UV light. Optionally, because the light extraction occurs from the backside of UV LED 900, laser liftoff and backside roughening 170 can be performed to enhance UV light extraction. It should be understood that a DBR is only one example of a reflecting layer that can be used in UV LED 900.

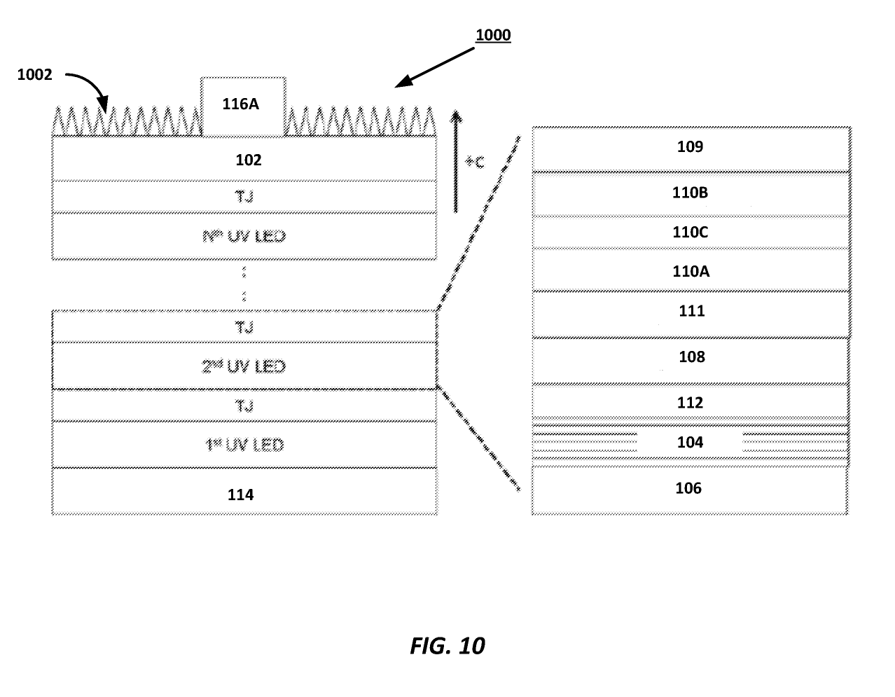

Referring now to FIG. 10, another example cascaded UV LED is described. The cascaded UV LED 1000 of FIG. 10 is similar in many respects to the cascaded UV LED of FIG. 4, and therefore, a number of the features of the cascaded UV LED of FIG. 10 are not described in detail below. As shown in FIG. 10, the cascaded UV LED has a roughened surface 1002, which enhances UV light extraction.

An example method of manufacturing an ultraviolet (UV) light emitting diode (LED) is described herein. The method can include forming a lower n-doped contact region (e.g., the second n-doped contact region 114 described herein) on a substrate; forming an n-doped cladding layer (e.g., the n-doped region 106 described herein) on the lower n-doped contact region; forming an active region (e.g., the active region 104 described herein) configured to emit UV light on the n-doped cladding layer; forming an electron blocking layer (e.g., the electron blocking region 112 described herein) on the active region; forming an p-doped cladding layer (e.g., the p-doped region 108 described herein) on the electron blocking layer; forming a tunnel junction (e.g., the tunnel junction 110 described herein) on the p-doped cladding layer; and forming an upper n-doped contact region (e.g., the n-doped contact region 102 described herein) on the tunnel junction. In addition, the tunnel junction can include a heavily p-doped region (e.g., p-AlGaN compositional grading layer), a degenerately n-doped region (e.g., n-AlGaN compositional grading layer), and a semiconductor region (e.g., InGaN layer) arranged between the heavily p-doped region and the degenerately n-doped region. Each of the heavily p-doped region and the degenerately n-doped region has a gradually varied material energy bandgap to reduce a depletion barrier within the heavily p-doped region and the degenerately n-doped region.

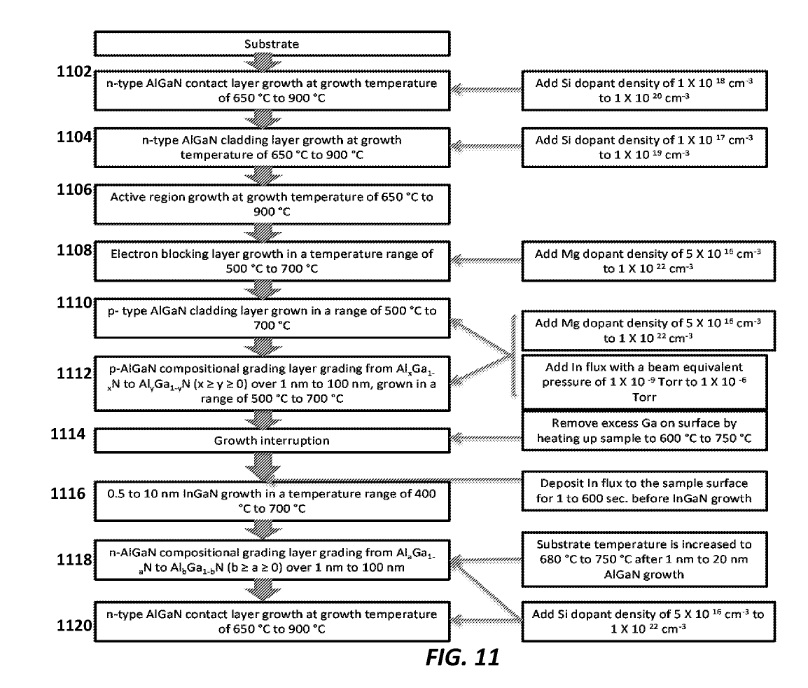

Referring now to FIG. 11, a flow diagram illustrating example operations for manufacturing an AlGaN-based UV LED is shown. It should be understood that the operations for manufacturing the AlGaN-based UV LED of FIG. 11 are provided only as an example and that other materials, temperature ranges, composition ranges, and/or dopant concentration ranges can be used. At 1102, a lower n-doped contact region (e.g., an n-type AlGaN contact layer) is grown on a substrate. The n-type AlGaN contact layer can be grown at a growth temperature from about 650° C. to about 900° C. Additionally, Si dopant can be added to a density of about 1×10¹⁸ cm⁻³ to about 1×10²⁰ cm⁻³. At 1104, an n-doped cladding layer (e.g., an n-type AlGaN cladding layer) is grown on the n-type AlGaN contact layer. The n-doped cladding layer can be grown at a growth temperature from about 650° C. to about 900° C. Additionally, Si dopant can be added to a density of about 1×10¹⁷ cm⁻³ to about 1×10¹⁹ cm⁻³. At 1106, an active region is grown on the n-doped cladding layer. The active region can be grown at a growth temperature from about 650° C. to about 900° C.

At 1108, an electron blocking layer is grown on the active layer. The electron blocking layer can be grown at a growth temperature from about 500° C. to about 700° C. Additionally, Mg dopant can be added to a density of about 5×10¹⁶ cm⁻³ to about 1×10²² cm⁻³. At 1110, a p-doped cladding layer (e.g., a p-type AlGaN cladding layer) is grown on the electron blocking layer. The p-type AlGaN cladding layer can be grown at a growth temperature from about 500° C. to about 700° C. Additionally, Mg dopant can be added to a density of about 5×10¹⁶ cm⁻³ to about 1×10²² cm⁻³. At 1112, a heavily p-doped region (e.g., p-AlGaN compositional grading layer of FIG. 11) with graded material energy bandgap is grown on the p-type AlGaN cladding layer. It should be understood that the p-AlGaN compositional grading layer is part of the tunnel junction described herein. The energy bandgap of the heavily p-doped region can be graded from AlₓGa₁₋ₓN to Al_{y}Ga_{1-y}N (x≧y≧0) over about 1 nm to about 100 nm thickness. The p-AlGaN compositional grading layer can be grown at a growth temperature from about 500° C. to about 700° C. The AlGaN energy bandgap can be graded by changing Al temperature for the designed fluxes, by pulsing Al flux to reduce AlGaN energy bandgap, by pulsing N flux to increase AlGaN energy bandgap, and/or by combinations of changing Al temperature with flux pulsing. Additionally, Mg dopant can be added to a density of about 5×10¹⁶ cm⁻³ to about 1×10²² cm⁻³. Further, an indium (In) flux can be pulsed with a beam equivalent pressure from about 1×10⁻⁹ Torr to about 1×10⁻⁶ Torr in steps 1110 and/or 1112 to assist Mg incorporation.

At step 1114, growth is interrupted after formation of the p-AlGaN compositional grading layer. In particular, excess Ga on the surface can be removed (e.g., desorbed) by heating from about 600° C. to about 750° C. During the interruption, an In flux can be deposited to the surface of the p-AlGaN compositional grading layer for about 1 second to about 600 seconds. Then, at 1116, an InGaN layer is grown on the p-AlGaN compositional grading layer. It should be understood that the InGaN layer is part of the tunnel junction described herein. Additionally, the InGaN layer can be grown to a thickness of about 0.5 nm to about 10 nm at a growth temperature from about 400° C. to about 700° C. At 1118, a degenerately n-doped region (e.g., n-AlGaN compositional grading layer) with graded material energy bandgap is grown on the InGaN layer. It should be understood that the n-AlGaN compositional grading layer is part of the tunnel junction described herein. The n-AlGaN compositional grading layer can be grown directly after growth of the InGaN layer without interruption. The energy bandgap of the degenerately n-doped region can be graded from AlₐGa₁₋ₐN to Al_{b}Ga_{1-b}N (b≧a≧0) over about 1 nm to about 100 nm thickness. The AlGaN energy bandgap can be graded by changing Al temperature for the designed fluxes, by pulsing Al flux to reduce AlGaN energy bandgap, by pulsing N flux to increase AlGaN energy bandgap, and/or by combinations of changing Al temperature with flux pulsing. Additionally, Si dopant can be added to a density of about 5×10¹⁶ cm⁻³ to about 1×10²² cm⁻³. The n-AlGaN compositional grading layer can be grown at a growth temperature increasing to about 680° C. to about 750° C. after about 1 nm to about 20 nm of growth with a ramp rate of about 10 to about 100° C./minute. Further, gallium (Ga) flux can be increased to maintain a monolayer from about 1 nm to about 10 nm of Ga on the surface. At 1120, an upper n-doped contact region (e.g., an n-type AlGaN contact layer) is grown on a substrate. The n-type AlGaN contact layer can be grown at a growth temperature from about 650° C. to about 900° C. Additionally, Si dopant can be added to a density of about 5×10¹⁶ cm⁻³ to about 1×10²² cm⁻³.

Advantages

To solve both the low EQE and low WPE problems, a tunnel injected UV LED design using an AlGaN/InGaN/AlGaN tunnel junction (TJ) as tunnel contact to a p-AlGaN cladding layer is described herein. Compared to the thermal injection of holes which degrades exponentially with increasing AlGaN bandgap, the tunnel junction takes advantage of non-equilibrium hole injection through tunneling which is not limited by the thermal activation energy of acceptors. This increases the injection efficiency especially for deep UV LEDs in which the acceptor activation energy will be high. Another advantage of tunnel junction contact is that it enables n-type top or upper contact instead of p-type contact, so that the contact resistance is reduced and the voltage drop across the contact is low. As a result, the WPE is increased. Additionally, since there is no low energy bandgap p-type contact layer on the top or upper surface of the UV LED, the emitted UV light can be collected directly from the top surface with almost no absorption loss. Thus, flip chip bonding is unnecessary. The UV light extraction efficiency can be as high as 70% to 80% (similar to the light extraction efficiency achieved by GaN/InGaN based visible LEDs), which is several times higher than the achieved value for conventional UV LEDs with p-type absorbing contact layers.

Although the subject matter has been described in language specific to structural features and/or methodological acts, it is to be understood that the subject matter defined in the appended claims is not necessarily limited to the specific features or acts described above. Rather, the specific features and acts described above are disclosed as example forms of implementing the claims.

1. An ultraviolet (UV) light emitting diode (LED), comprising:
an n-doped contact region;
an active region configured to emit UV light, the active region being arranged between an n-doped region and a p-doped region; and
a tunnel junction arranged between the n-doped contact region and the p-doped region, the tunnel junction comprising:
a heavily p-doped region,
a degenerately n-doped region, and
a semiconductor region arranged between the heavily p-doped region and the degenerately n-doped region, wherein each of the heavily p-doped region and the degenerately n-doped region has a gradually varied material energy bandgap to reduce respective depletion barriers within the heavily p-doped region and the degenerately n-doped region.

2. The UV LED of claim 1, wherein the semiconductor region forms respective heterojunctions to the heavily p-doped region and the degenerately n-doped region to establish a polarization field that aligns a valence band of the heavily p-doped region and a conduction band of the degenerately n-doped region.

3. The UV LED of claim 1, wherein an energy bandgap of at least one of the heavily p-doped region or the degenerately n-doped region is larger than an energy bandgap of one or more quantum wells of the active region.

4. The UV LED of claim 1, wherein the gradually varied material energy bandgap of the heavily p-doped region comprises a relatively increasing energy bandgap of semiconductor material moving away from an interface with the semiconductor region.

5. The UV LED of claim 1, wherein the gradually varied material energy bandgap of the degenerately n-doped region comprises a relatively increasing energy bandgap of semiconductor material moving away from an interface with the semiconductor region.

6. The UV LED of claim 4, wherein the semiconductor material comprises at least one of aluminum gallium nitride (AlGaN), gallium nitride (GaN), or indium aluminum gallium nitride (InAlGaN).

7. The UV LED of claim 1, wherein the tunnel junction comprises an inter band tunnel barrier in the semiconductor region, an n-depletion barrier in the degenerately n-doped region, and a p-depletion barrier in the heavily p-doped region.

8. The UV LED of claim 1, wherein a thickness of the degenerately n-doped region with the gradually varied material energy bandgap is from about 1 nm to about 100 nm.

9. The UV LED of claim 1, wherein a thickness of the heavily p-doped region with the gradually varied material energy bandgap is from about 1 nm to about 100 nm.

10. The UV LED of claim 1, wherein a thickness of the semiconductor region is from about 0.5 nm to about 10 nm.

11. The UV LED of claim 10, wherein the semiconductor region has lateral material energy bandgap fluctuations comprising a plurality of low and high bandgap regions.

12. The UV LED of claim 10, wherein the semiconductor region comprises at least one of indium gallium nitride (InGaN), GaN, AlGaN, or InAlGaN.

13. The UV LED of claim 1, further comprising an electron blocking region arranged between the active region and the p-doped region.

14. The UV LED of claim 1, further comprising a second n-doped contact region, wherein the n-doped region is arranged on the second n-doped contact region.

15. The UV LED of claim 1, wherein the tunnel junction is reversed biased during operation of the UV LED.

16. The UV LED of claim 1, wherein the n-doped contact region comprises a roughened surface configured to enhance UV light extraction.

17. The UV LED of claim 14, wherein the second n-doped contact region comprises a roughened surface configured to enhance UV light extraction.

18. The UV LED of claim 1, further comprising a dielectric layer arranged on the n-doped contact region.

19. The UV LED of claim 18, wherein the dielectric layer has a larger energy bandgap than an emission energy of the active region.

20. The UV LED of claim 18, wherein a thickness of the dielectric layer is from about 10 nm to about 10 μm.

21. The UV LED of claim 18, wherein a refractive index of the dielectric layer is less than a refractive index of the n-doped contact region.

22. The UV LED of claim 18, wherein the dielectric layer has a variable refractive index.

23. The UV LED of claim 18, wherein the dielectric layer comprises a roughened surface configured to enhance UV light extraction.

24. The UV LED of claim 18, wherein at least one of the dielectric layer or the n-doped contact region comprises a lattice of spaces.

25. The UV LED of claim 24, wherein the lattice of spaces forms a photonic crystal structure in the at least one of the dielectric layer or the n-doped contact region, the photonic crystal structure being configured to enhance UV light extraction.

26. The UV LED of claim 24, wherein the lattice of spaces forms an array of UV LED columns.

27. The UV LED of claim 18, wherein the dielectric layer comprises a distribution Bragg reflector.

28. The UV LED of claim 1, further comprising an inverted lattice polarity layer arranged on the n-doped contact region, the inverted lattice polarity layer having a thickness from about 5 nm to about 10 μm.

29. The UV LED of claim 28, wherein the inverted lattice polarity layer comprises a roughened surface.

30. The UV LED of claim 28, wherein the inverted lattice polarity layer is obtained by changing the epitaxial growth schemes using different epitaxial methods.

31. The UV LED of claim 1, further comprising a contact region arranged on at least one of the n-doped contact region or the second n-doped contact region.

32. The UV LED of claim 30, wherein the contact region has a gradually varied material energy bandgap.

33. A cascaded ultraviolet (UV) light emitting diode (LED), comprising a plurality of UV LEDs according to claim 1.

34. The cascaded UV LED of claim 33, wherein respective quantum well energy bandgaps of the active regions of the UV LEDs are the same.

35. The cascaded UV LED of claim 33, wherein respective quantum well energy bandgaps of the active regions of the UV LEDs are different.

36. A method of manufacturing an ultraviolet (UV) light emitting diode (LED), comprising:
forming a lower n-doped contact region on a substrate;
forming an n-doped cladding layer on the lower n-doped contact region;
forming an active region on the n-doped cladding layer, the active region being configured to emit UV light;
forming an electron blocking layer on the active region;
forming an p-doped cladding layer on the electron blocking layer;
forming a tunnel junction on the p-doped cladding layer; and
forming an upper n-doped contact region on the tunnel junction, wherein the tunnel junction comprises:
a heavily p-doped region,
a degenerately n-doped region, and
a semiconductor region arranged between the heavily p-doped region and the degenerately n-doped region, wherein each of the heavily p-doped region and the degenerately n-doped region has a gradually varied material energy bandgap to reduce respective depletion barriers within the heavily p-doped region and the degenerately n-doped region.
